(19) United States
(12) Patent Application Publication
(10) Pub. No.: US 2008/0124859 A1
(43) Pub. Date: May 29, 2008

(54) Methods of Forming CMOS Integrated Circuits Using Gate Sidewall Spacer Reduction Techniques

(76) Inventors: Min Chul Sun, Gyeonggi-do (KR); Jong Ho Yang, Fishkill, NY (US); Young Gun Ko, Fishkill, NY (US); Ja Hum Ku, Gyeonggi-do (KR); Jae Eon Park, Gyeonggi-do (KR); Jeong Hwan Yang, Gyeonggi-do (KR); Christopher Vincent Baiocco, Newburgh, NY (US); Gerald Leake, McKeesport, PA (US)

Correspondence Address: MYERS BIGEL SIBLEY & SAJOVEC, PO BOX 37428, RALEIGH, NC, 27627, US

(21) Appl. No.: 11/563,476

(22) Filed: Nov. 27, 2006

(51) Int. Cl. H01L 21/8238; H01L 21/336

(52) U.S. Cl. 438/230; 438/303; 257/E21.409; 257/E21.632

(57) ABSTRACT

Methods of forming field effect transistors include methods of forming PMOS and NMOS transistors by forming first and second gate electrodes on a substrate and then forming an electrically insulating layer having etch-enhancing impurities therein, on the first and second gate electrodes. The electrically insulating layer may be formed as a boron-doped silicon nitride layer or an electrically insulating layer that is doped with germanium and/or fluorine. The electrically insulating layer is etched-back to define first sidewall spacers on the first gate electrode and second sidewall spacers on the second gate electrode. P-type source and drain region dopants are then implanted into the semiconductor substrate, using the first sidewall spacers as a first implant mask. The second sidewall spacers on the second gate electrode are then etched back to reduce their lateral dimensions. N-type source and drain region dopants are then implanted into the semiconductor substrate, using the second sidewall spacers with reduced lateral dimensions as a second implant mask.

### FIELD OF THE INVENTION

The present invention relates to integrated circuit fabrication methods and, more particularly, to methods of fabricating field effect transistors in integrated circuit substrates.

### BACKGROUND OF THE INVENTION

CMOS integrated circuit fabrication methods include steps to form PMOS and NMOS field effect transistors in a common semiconductor substrate. However, because PMOS and NMOS transistors may be susceptible to different parasitic influences, such as short channel effects (SCE), CMOS integrated circuit fabrication methods may need to include additional steps that uniquely address the parasitics associated with PMOS transistors or NMOS transistors. One conventional CMOS integrated circuit fabrication method includes forming insulated gate electrodes with first sidewall spacers and then thickening the sidewall spacers by depositing a disposable tetraethylorthosilicate (TEOS) glass layer on the insulated gate electrodes. A step is then performed to selectively implant P-type source and drain region dopants into the substrate using the first sidewall spacers and disposable TEOS glass layer as an implant mask. This selective implant step is performed in order to define the heavily doped P-type source and drain regions for the PMOS transistors. The disposable TEOS glass layer is then removed and followed by a step to selectively implant N-type source and drain region dopants into the substrate using the first sidewall spacers (without disposable TEOS glass layer) as an implant mask. This selective implant step is performed in order to define the heavily doped N-type source and drain regions for the NMOS transistors. These N-type source and drain regions extend closer to the channel regions of the NMOS transistors relative to the distance between the P-type source and drain regions and the channel regions of the PMOS transistors. In this manner, the use of the disposable TEOS glass layer can improve the short channel characteristics of the PMOS transistors, which are typically more susceptible to short channel effects relative to NMOS transistors.

### SUMMARY OF THE INVENTION

Embodiments of the invention include methods of forming field effect transistors that take into account different short channel characteristics associated with PMOS and NMOS transistors. According to some of these embodiments, methods of forming field effect transistors include methods of forming PMOS and NMOS transistors within a semiconductor substrate. These methods include forming first and second gate electrodes (e.g., insulated gate electrodes) on a semiconductor substrate and then forming an electrically insulating layer having etch-enhancing impurities therein, on the first and second gate electrodes. The electrically insulating layer may be formed as a boron-doped silicon nitride layer (i.e., borosiliconnitride) or as an electrically insulating layer that is doped with germanium and/or fluorine. This doping of the electrically insulating layer may be performed as an in-situ doping step or by implanting dopants into the electrically insulating layer. The electrically insulating layer is etched-back to define first sidewall spacers on the first gate electrode and second sidewall spacers on the second gate electrode. P-type source and drain region dopants are then implanted into the semiconductor substrate, using the first sidewall spacers as a first implant mask. This implanting step is performed to define source and drain regions of a PMOS transistor. The second sidewall spacers on the second gate electrode are then etched back to reduce their lateral dimensions. N-type source and drain region dopants are then implanted into the semiconductor substrate, using the second sidewall spacers with reduced lateral dimensions as a second implant mask.

Still further embodiments of the present invention include methods of forming a field effect transistor by forming a gate electrode having electrically insulating spacers on sidewalls thereof and implanting etch-enhancing impurities selected from a group consisting of germanium and fluorine into the electrically insulating spacers. The electrically insulating spacers are etched-back to reduce their lateral dimensions and then source and drain region dopants are implanted into the semiconductor substrate using the sidewall spacers with reduced lateral dimensions as an implant mask.

### BRIEF DESCRIPTION OF THE DRAWINGS

FIGS. 1A-1C are cross-sectional views of intermediate structures that illustrated methods of forming field effect transistors according to some embodiments of the invention.

FIGS. 2A-2F are cross-sectional views of intermediate structures that illustrated methods of forming CMOS integrated circuits according to some embodiments of the invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

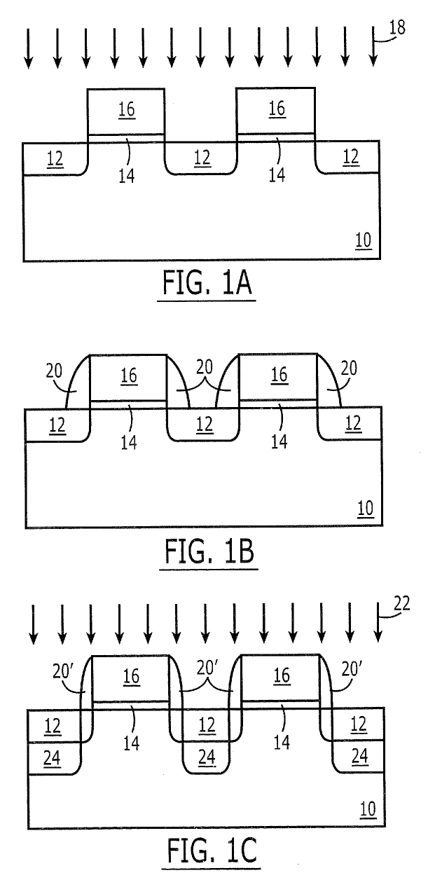

Referring now to FIGS. 1A-1C, methods of forming field effect transistors according to embodiments of the present invention include the steps of forming a gate insulating layer and a gate electrode layer in sequence on a semiconductor substrate 10. The gate insulating layer and the gate electrode layer are then selectively patterned to define a plurality of insulated gate electrodes on a surface of the substrate 10. Each of these insulated gate electrodes includes a gate electrode 16 and a gate insulating region 14. The formation of the insulated gate electrodes is followed by a step of selectively implanting source/drain region dopants 18 into the substrate 10, using the insulated gate electrodes as an implant mask. These source/drain region dopants may be implanted at a relatively low energy and dose level to thereby support the formation of lightly doped source/drain regions 12 (i.e., LDD regions) within the substrate 10. In particular, an annealing step may be performed to at least partially drive-in the implanted dopants (vertically and horizontally).

Insulating spacers 20 are then formed on sidewalls of the insulated gate electrodes, as illustrated by FIG. 1B. These insulating spacers 20 may be formed by conformally depositing an electrically insulating layer on the substrate and on the insulated gate electrodes and then etching back the deposited layer to define the sidewall spacers 20. According to aspects of embodiments of the invention, the insulating spacers 20 are formed to include etch-enhancing impurities therein. In particular, the deposited electrically insulating layer that is patterned to form the sidewall insulating spacers may be formed as a boron-doped silicon nitride layer (i.e., borosiliconnitride) or as an electrically insulating layer that is doped with germanium and/or fluorine. This doping of the electrically insulating layer may be performed as an in-situ doping step while the electrically insulating layer is being deposited or by implanting etch-enhancing dopants into an already deposited electrically insulating layer.

Referring now to FIG. 1C, the sidewall spacers are etched back to reduce their lateral dimensions and define thinner sidewall spacers 20′. Source and drain region dopants 22 are then implanted into the semiconductor substrate, using the insulated gate electrodes and the sidewall spacers 20′ with reduced lateral dimensions as an implant mask. This implantation, which typically occurs at a relatively high dose level and is followed by an annealing step to drive-in the implanted dopants, results in the formation of the relatively highly doped source/drain regions 24.

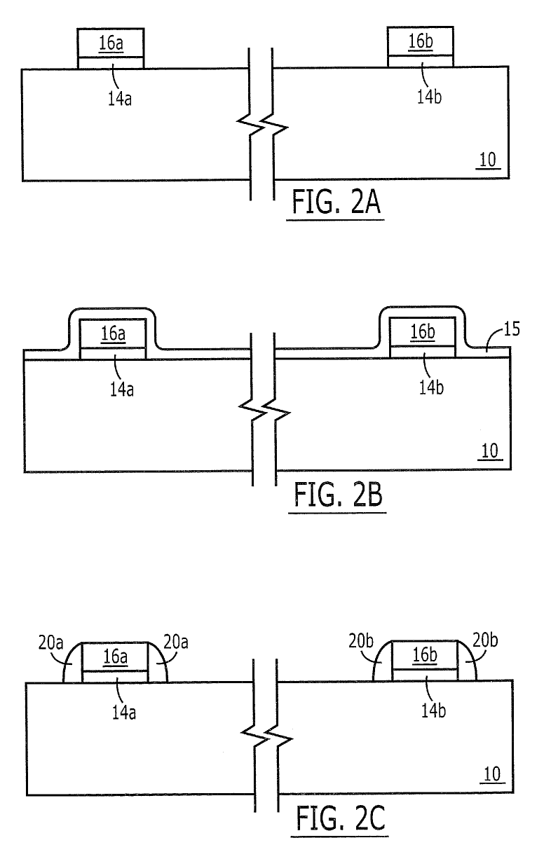

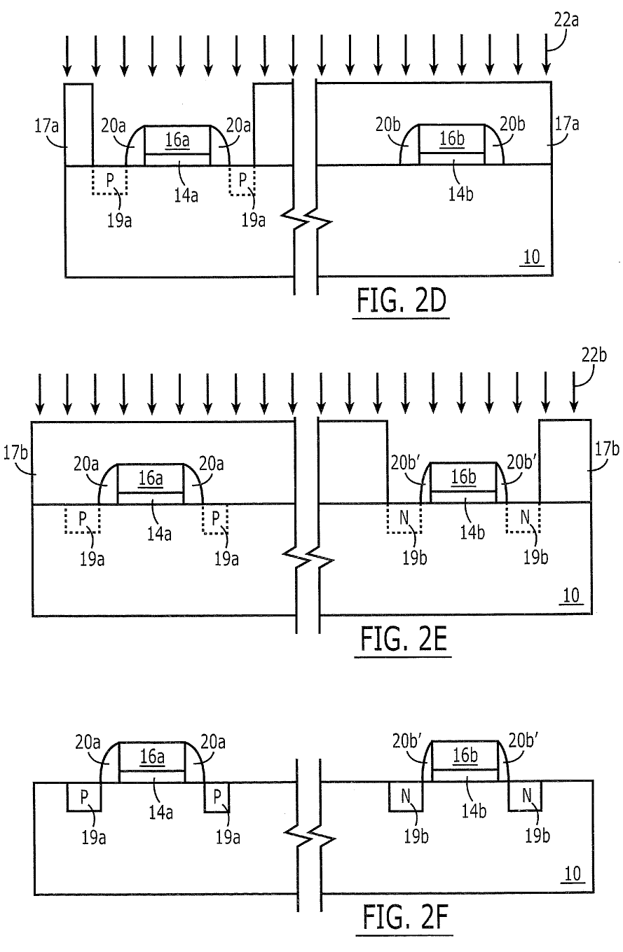

Referring now to FIGS. 2A-2F, methods of forming CMOS integrated circuits according to additional embodiments of the present invention include the steps of forming a gate insulating layer and a gate electrode layer in sequence on a semiconductor substrate 10. The gate insulating layer and the gate electrode layer are then selectively patterned to define a plurality of insulated gate electrodes on a surface of the substrate 10. These insulated gate electrodes includes a gate electrode 16a and a gate insulating region 14a associated with a PMOS transistor and a gate electrode 16b and a gate insulating region 14b associated with an NMOS transistor. The formation of the insulated gate electrodes for the PMOS and NMOS transistors may then be followed by the steps of selectively implanting P-type and N-type source/drain region dopants into the substrate 10 to define LDD regions (not shown).

Insulating spacers 20a and 20b are then formed on sidewalls of the insulated gate electrodes for the PMOS and NMOS transistors, respectively. As illustrated by FIGS. 2B-2C, these insulating spacers 20a and 20b may be formed by conformally depositing an electrically insulating layer 15 on the substrate and on the insulated gate electrodes and then etching back the deposited layer to define the sidewall spacers 20a and 20b. According to aspects of embodiments of the invention, the insulating spacers 20 are formed to include etch-enhancing impurities/dopants therein. In particular, the deposited electrically insulating layer 15 that is patterned to form the sidewall insulating spacers may be formed as a boron-doped silicon nitride layer (i.e., borosiliconnitride) or as an electrically insulating layer that is doped with germanium and/or fluorine. These dopants (boron, germanium, fluorine, . . . ) operate to increase the etching rate of the deposited insulating layer. According to aspects of these embodiments, the doping of the electrically insulating layer may be performed as an in-situ doping step while the electrically insulating layer is being deposited or by blanket implanting etch-enhancing dopants into an already deposited electrically insulating layer 15.

Referring now to FIG. 2D, a P-type dopant implant mask 17a is formed on the substrate 10 and patterned to define an opening(s) therein that exposes an insulated gate electrode of a PMOS transistor. P-type source/drain region dopants 22a are then implanted into the substrate 10, using the implant mask 17a and the insulated gate electrode (and sidewall spacers 20a) as an implant mask. This implant step (and possibly a subsequent annealing/drive-in step) results in the formation of P-type source and drain regions 19a in the substrate 10. These P-type source and drain regions 19a are self-aligned to the sidewall spacers 20a.

Referring now to FIG. 2E, an N-type dopant implant mask 17b is formed on the substrate 10 and patterned to define an opening(s) therein that exposes an insulated gate electrode of an NMOS transistor. A relatively short-duration etching step may then be performed etch-back the sidewall spacers 20b. This etching step results in the formation of spacers 20b′ having reduced lateral dimensions. N-type source/drain region dopants 22b are then implanted into the substrate 10, using the implant mask 17b and the insulated gate electrode (and narrower sidewall spacers 20b′) as an implant mask. This implant step (and possibly a subsequent annealing/drive-in step) results in the formation of N-type source and drain regions 19b in the substrate 10. These N-type source and drain regions 19b are self-aligned to the sidewall spacers 20b′. Referring now to FIG. 2F, the N-type dopant implant mask 17b is then removed to expose the PMOS transistor (left side) and the NMOS transistor (right side) having narrower sidewall spacers 20b′.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming a field effect transistor, comprising the steps of:
forming a gate electrode having electrically insulating spacers on sidewalls thereof;
implanting etch-enhancing impurities selected from a group consisting of germanium and fluorine into the electrically insulating spacers;
etching back the electrically insulating spacers to reduce their lateral dimensions; and
implanting source/drain dopants of first conductivity type into the semiconductor substrate, using the electrically insulating spacers with reduced lateral dimensions as an implant mask.

2. The method of claim 1, wherein the electrically insulating spacers comprise silicon nitride.

3. A method of forming a field effect transistor, comprising the steps of:
forming a gate electrode on a semiconductor substrate;
forming electrically insulating sidewall spacers having electrically inactive etch-enhancing impurities incorporated therein, on sidewalls of the gate electrode;
etching back the electrically insulating sidewall spacers to reduce their lateral dimensions; and
implanting source/drain dopants of first conductivity type into the semiconductor substrate, using the sidewall spacers with reduced lateral dimensions as an implant mask.

4. The method of claim 3, wherein the electrically inactive etch-enhancing impurities are selected from a group consisting of germanium and fluorine.

5. The method of claim 3, wherein the electrically insulating sidewall spacers comprise borosiliconnitride (BSiN).

6. The method of claim 3, wherein said step of forming electrically insulating sidewall spacers comprises depositing an in-situ doped electrically insulating layer on the gate electrode.

7. A method of forming a field effect transistor, comprising the steps of:
forming first and second gate electrodes on a semiconductor substrate;
forming an electrically insulating layer having etch-enhancing impurities therein, on the first and second gate electrodes;
etching-back the electrically insulating layer to define first sidewall spacers on the first gate electrode and second sidewall spacers on the second gate electrode;
implanting P-type source/drain region dopants into the semiconductor substrate, using the first sidewall spacers as an implant mask;
etching-back the second sidewall spacers to reduce their lateral dimensions; and
implanting N-type source/drain region dopants into the semiconductor substrate, using the second sidewall spacers with reduced lateral dimensions as an implant mask.

8. The method of claim 7, wherein the electrically insulating layer comprises boron-doped silicon nitride.

9. The method of claim 7, wherein said step of forming an electrically insulating layer comprises implanting germanium and/or fluorine into the electrically insulating layer.
